(19) United States
(12) Patent Application Publication
(10) Pub. No.: US 2026/0276741 A1
(43) Pub. Date: Sep. 17, 2026

(54) Method and Apparatus for Determining Maintenance of DC Busbar Filtering Electrolytic Capacitor

(71) Applicant: Siemens Aktiengesellschaft, München (DE)

(72) Inventors: Kai Jiang, Nanjing, JS (CN); Yan Hua Guo, Nanjing, JS (CN)

(73) Assignee: Siemens Aktiengesellschaft, München (DE)

(21) Appl. No.: 19/167,534

(22) PCT Filed: Mar. 28, 2023
(86) PCT No.: PCT/CN2023/084507

§ 371 Date: Sep. 22, 2025

(51) Int. Cl. G01R 31/64

(52) U.S. Cl. CPC G01R 31/64

(57) ABSTRACT

Various embodiments include methods for determining maintenance of a DC busbar filtering electrolytic capacitor. An example includes: recording a DC busbar voltage of a capacitor in a driving circuit of a driving motor during charging capacitor, wherein the is the difference between voltages at two ends of the capacitor; determining a charging starting time point and a charging ending time point according to the recorded DC busbar voltages, and selecting a time point from time points between the charging starting time point and the charging ending time point; calculating a time constant according to a starting voltage corresponding to the charging starting time point, an ending voltage corresponding to the charging ending time point, the selected time point and the voltage corresponding to the selected time point; and determining whether it is necessary to perform maintenance for the capacitor based on the time constant.

### CROSS-REFERENCE TO RELATED APPLICATIONS

This application is a U.S. National Stage Application of International Application No. PCT/CN2023/084507 filed Mar. 28, 2023, which designates the United States of America, the contents of which are hereby incorporated by reference in their entirety.

### TECHNICAL FIELD

The present disclosure relates to driving motors. Various embodiments of the teachings herein include method and/or devices for determining maintenance of a DC busbar filtering electrolytic capacitor.

### BACKGROUND

A DC busbar filtering electrolytic capacitor is a key component in a driving motor and its failure rate is much higher than other components. Therefore, its maintenance is essential in the routine maintenance of the driving motor. However, a critical issue for the user is how to determine the maintenance time point(s) to reduce downtime of the driving motor.

### SUMMARY

Teachings of the present disclosure include methods, devices, and media for determining maintenance of a DC busbar filtering electrolytic capacitor. The teachings make it possible to accurately determine whether it is necessary to perform maintenance for the DC busbar filtering electrolytic capacitor.

For example, some embodiments of the teachings herein include a method for determining maintenance of a DC busbar filtering electrolytic capacitor, comprising: recording a DC busbar voltage of the DC busbar filtering electrolytic capacitor in a driving circuit of a driving motor during charging of the DC busbar filtering electrolytic capacitor wherein the DC busbar voltage is a difference between voltages at two ends of the DC busbar filtering electrolytic capacitor; determining a charging starting time point and a charging ending time point according to the recorded DC busbar voltages, and selecting a time point from time points between the charging starting time point and the charging ending time point; calculating a time constant according to a starting voltage corresponding to the charging starting time point, an ending voltage corresponding to the charging ending time point, the selected time point and the DC busbar voltage corresponding to the selected time point; and determining whether it is necessary to perform maintenance for the DC busbar filtering electrolytic capacitor, according to the time constant.

As another example, some embodiments include a device for determining maintenance of a DC busbar filtering electrolytic capacitor, comprising: a data recording module, for recording a DC busbar voltage of the DC busbar filtering electrolytic capacitor in a driving circuit of a driving motor during charging of the DC busbar filtering electrolytic capacitor wherein the DC busbar voltage is a difference between voltages at two ends of the DC busbar filtering electrolytic capacitor; a first determination module, for determining a charging starting time point and a charging ending time point according to the recorded DC busbar voltages, and selecting a time point from time points between the charging starting time point and the charging ending time point; a parameter calculation module, for calculating a time constant according to a starting voltage corresponding to the charging starting point, time an ending voltage corresponding to the charging ending time point, the selected time point and the DC busbar voltage corresponding to the selected time point; and a second determination module, for determining whether it is necessary to perform maintenance for the DC busbar filtering electrolytic capacitor, according to the time constant.

As another example, some embodiments include a computer-readable storage medium. It is stored thereon with a computer program, and when the computer program is executed in a computer, one or more of the methods described herein is implemented by the computer.

As another example, some embodiments include a calculation apparatus. It comprises a memory and a processor wherein the memory is stored therein with executable codes, and when the executable codes are executed by the processor, one or more of the methods described herein is implemented.

### DESCRIPTION OF THE DRAWINGS

In order to explain the technical solutions more clearly, the figures used for description are briefly introduced as below. The figures in the description below represent only some embodiments of the teachings of the present disclosure. Based on these figures, those skilled in the art can obtain other figures without any inventive work. In the drawings:

FIG. 1 is a flowchart of an example method for determining maintenance of a DC busbar filtering electrolytic capacitor incorporating teachings of the present disclosure;

FIG. 2 is a circuit diagram of an example driving motor incorporating teachings of the present disclosure; and

FIG. 3 is a structural block diagram of an example device for determining maintenance of a DC busbar filtering electrolytic capacitor incorporating teachings of the present disclosure.

### REFERENCE NUMERALS

| S110~S140 | steps |
|---|---|
| 200 | device for determining maintenance of DC |
| | busbar filtering electrolytic capacitor |
| 210 | first determination module |
| 220 | first determination module |
| 230 | parameter calculation module |
| 240 | second determination module |
| 10 | driving circuit |
| 20 | motor |
| 11 | current limiting resistor |
| 12 | switch |
| 13 | DC busbar filtering electrolytic capacitor |
| 14 | Input end of three-phase power supply |

### DETAILED DESCRIPTION

The methods, devices, media, and apparatus described herein for determining maintenance of a DC busbar filtering electrolytic capacitor, individually or in combination, can provide one or more of the following technical effects:

(1) First, it is to record a DC busbar voltage of the DC busbar filtering electrolytic capacitor in a driving circuit of a driving motor during charging of the DC busbar filtering electrolytic capacitor; then it is to determine a charging starting time point and a charging ending time point according to the recorded DC busbar voltages, and select a time point from time points between the charging starting time point and the charging ending time point; then it is to calculate a time constant according to a starting voltage corresponding to the charging starting time point, an ending voltage corresponding to the charging ending time point, the selected time point and the DC busbar voltage corresponding to the selected time point; and further, it is to determine whether it is necessary to perform maintenance for the DC busbar filtering electrolytic capacitor, according to the time constant. As the time constant is a product of the resistance of the current limiting resistor and the capacitance of the DC busbar filtering electrolytic capacitor, and the resistance of the current limiting resistor is constant, the time constant reflects the capacitance of the DC busbar filtering electrolytic capacitor. Therefore, when the capacitance, as reflected by the time constant, is decreased to a certain degree, it is determined that it is necessary to perform maintenance for the DC busbar filtering electrolytic capacitor.

It is to set the current time point as the a maintenance time point and then inform the user of the maintenance time point, and thus the user is informed that it is necessary to perform maintenance for the DC busbar filtering electrolytic capacitor. The capacitance is used to determine whether it is necessary to perform maintenance and the capacitance may be changed due to influence by surrounding factors, such as temperature, current ripple, voltage ripple, and so on. Therefore, compared with those methods of determining whether it is necessary to perform maintenance depending on the use time period of the electrolytic capacitor, the methods as provided consider practical working circumstances, with more accurate determination for the lifetime of the capacitor. That is, the determination for the maintenance time point is more accurate, thus reducing downtime of the driving motor.

(2) In some embodiments, for the first charging process, if the DC busbar voltage is 0V and the switch is in the switch-on state, it is to control the switch to switch off; and if the DC busbar voltage is 0V and the switch is in the switch-off state, it is to maintain the switch-off state of the switch. When the switch-off state of the switch is maintained, it is possible to perform current limitation to the charging process during charging, thus achieving the protection function. With the charging time increasing, the DC busbar voltage increases continuously, and when the DC busbar voltage is increased to the first preset voltage, it is to control the switch to switch on, thus reducing loss on the current limiting resistor.

The first preset voltage is less than the ending voltage. That is, the switch is switched on when the DC busbar voltage during charging is increased to a relatively high value, rather than at the charging ending time point. The reason is: the longer is the charging time, the slower is the charging rate, and the charging current is decreasing. Therefore, after the DC busbar voltage during charging becomes a relatively high value, it is not necessary to consider the problem of current limitation protection. In order to reduce the loss on the current limiting resistor, the current limiting resistor is shorted.

(3) In some embodiments, during discharging of the DC busbar filtering electrolytic capacitor, if the DC busbar voltage is decreased to below a second preset voltage, it is to control the switch to switch off. Generally, after the switch is switched on, it is maintained in the switch-on state. However, once the DC busbar voltage is decreased to a very low value, it is to control the switch to switch off. After the DC busbar voltage is decreased to a very low value, the charging current during recharging will be relatively high. In order to protect the circuit, the switch is switched off, thus achieving the function of circuit protection.

In order to make the objective(s), technical solutions and potential advantages of embodiments clearer, the technical solutions in some example embodiments will be described clearly and completely hereinafter in connection with the figures. The described embodiments are some embodiments, rather than all embodiments. Any other embodiments obtained based on the embodiments in the present disclosure by those skilled in the art without any inventive work will fall within the protection scope thereof.

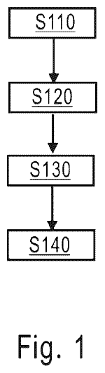

Some embodiments include a method for determining maintenance of a DC busbar filtering electrolytic capacitor. Referring to FIG. 1, the method comprises S110~S140:

S110: recording a DC busbar voltage of the DC busbar filtering electrolytic capacitor in a driving circuit of a driving motor during charging of the DC busbar filtering electrolytic capacitor wherein the DC busbar voltage is a difference between voltages at two ends of the DC busbar filtering electrolytic capacitor.

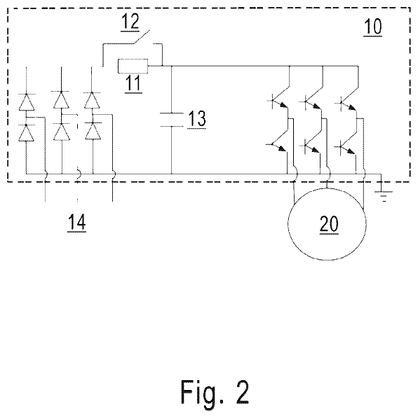

Referring to FIG. 2, the driving motor may comprise a driving circuit 10 and a motor 20. The driving circuit comprises six diodes, a current limiting resistor 11, a switch 12 connected parallel with the current limiting resistor, a DC busbar filtering electrolytic capacitor 13, and six triodes. Herein, the six diodes are used to perform rectification processing to the input three-phase power supply, with only the positive direction portion therein remained.

Then the six triodes are used to transform the rectified positive direction portion into an AC supply suitable for the motor, and the AC supply is further used to supply power to the motor. Herein, the three-phase power supply uses its input end 14 to supply input to the driving circuit. Herein, the DC busbar filtering electrolytic capacitor is charged and discharged alternately during the above process. With the switch in the switch-on state, it is possible to reduce the loss on the current limiting resistor; and with the switch in the switch-off state, it is possible to enable a function of current limiting to the whole driving circuit.

In practical circumstances, it is possible to record the voltages of the DC busbar filtering electrolytic capacitor in the driving circuit (i.e. the DC busbar voltages) in real time, to facilitate later determining the charging starting time point and the charging ending time point according to the recorded DC busbar voltages.

S120: determining a charging starting time point and a charging ending time point according to the recorded DC busbar voltages and selecting a time point from time points between the charging starting time point and the charging ending time point. In practical circumstances, in S120, there are different manners of determining the charging starting time point and the charging ending time point under different conditions. For the first charging process after power on of the driving circuit, the minimum value of the DC busbar voltage is 0; and for the non-first charging process after power on of the driving circuit, the minimum value of the DC busbar voltage is generally higher than 0. Therefore, it is necessary to distinguish whether the charging process is the first charging process after power on of the driving circuit.

In some embodiments, in S120, determining a charging starting time point and a charging ending time point according to the recorded DC busbar voltages may specifically comprise: if the charging process is the first charging process after power on of the driving circuit, setting the time point at which the DC busbar voltage during charging is 0V as the charging starting time point, and setting the time point at which the DC busbar voltage during charging has a variation amplitude less than a preset amplitude as the charging ending time point. That is, for the first charging process after power on of the driving circuit, it is to set the time point at which the DC busbar voltage is 0V as the charging starting time point. With the charging time increasing, the DC busbar voltage increases continuously. When the increasing amplitude of the DC busbar voltage becomes very small, it is considered that the charging is finished and thus the charging ending time point is obtained.

In some embodiments, in S120, determining a charging starting time point and a charging ending time point according to the recorded DC busbar voltages may specifically comprise: If the charging process is not the first charging process after power on of the driving circuit, setting the time point at which the DC busbar voltage during charging starts increasing as the charging starting time point, and setting the time point at which the DC busbar voltage during charging starts decreasing as the charging ending time point. That is, for the non-first charging process after power on of the driving circuit, in the charging process, the DC busbar voltage starts to increase, and when it is increased to a certain degree, the charging is finished. Then the DC busbar voltage starts decreasing and thus the discharging starts. After the discharging is finished, the charging starts, and again the DC busbar voltage starts increasing. Therefore, it is to set the time point at which the DC busbar voltage changes from the decreasing state to the increasing state as the charging starting time point and set the time point at which the DC busbar voltage changes from the increasing state to the decreasing state as the charging ending time point.

Herein, it is to select a time point from time points between the charging starting time point and the charging ending time point. For example, it is possible to select a middle time point between the charging starting time point and the charging ending time point. The middle time point is used as the selected time point, and the DC busbar voltage corresponding to the middle time point is used as the DC busbar voltage corresponding to the selected time point.

S130 calculating a time constant according to a starting voltage corresponding to the charging starting time point, an ending voltage corresponding to the charging ending time point, the selected time point and the DC busbar voltage corresponding to the selected time point. Herein, the time constant RC refers to a product of R and C wherein R is a resistance of the current limiting resistor 11 in the driving circuit and C is a capacitance of the DC busbar filtering electrolytic capacitor 13. Herein, the current limiting resistor has a constant resistance. As the DC busbar filtering electrolytic capacitor is an electrolytic capacitor, its capacitance will become lower and lower with time due to existence of the electrolyte. Therefore, the time constant can reflect the capacitance.

In some embodiments, it is possible to calculate the time constant by a first formula as below:

$$RC = t / ln [ ( V 1 - V 0 ) / ( V 1 - Vt ) ]$$

wherein RC is the time constant, t is the selected time point, Vt is the DC busbar voltage corresponding to the selected time point, V0 is the starting voltage, and V1 is the ending voltage.

During running of the motor, the DC busbar filtering electrolytic capacitor will be charged and discharged continuously. Therefore, it is possible to use the charging/discharging time to calculate the capacitance. Herein, the charging/discharging time t=RC×Ln [(V1−V0)/(V1−Vt)]. Next, by conversion of the formula of the charging time, the above first formula can be obtained.

S140 determining whether it is necessary to perform maintenance for the DC busbar filtering electrolytic capacitor, according to the time constant. It is understandable that if it is determined according to the time constant that it is necessary to perform maintenance for the DC busbar filtering electrolytic capacitor, it is possible to set the current time point as the a maintenance time point, and then inform the user of the maintenance time point, and thus the user is informed that it is necessary to perform maintenance for the DC busbar filtering electrolytic capacitor.

In some embodiments, in S140, determining whether it is necessary to perform maintenance for the DC busbar filtering electrolytic capacitor according to the time constant may specifically comprise: determining that it is necessary to perform maintenance for the DC busbar filtering electrolytic capacitor if the time constant is less than a preset threshold. It is understandable that the time constant is directly proportional to the capacitance. Thus, the smaller is the time constant, the smaller is the capacitance. Therefore, when the time constant is less than a preset threshold, the capacitance is decreased to a sufficient degree such that the maintenance is needed. Therefore, it is determined that it is necessary to perform maintenance for the DC busbar filtering electrolytic capacitor.

In some embodiments, referring to FIG. 2, the driving circuit comprises a current limiting resistor and a switch which are connected in parallel; and accordingly, the method may further comprise: if the charging process is the first charging process after power on of the driving circuit, controlling the switch to switch off when the DC busbar voltage during charging is 0V, and controlling the switch to switch on when the DC busbar voltage is increased to a first preset voltage less than the ending voltage. That is, for the first charging process, if the DC busbar voltage is 0V and the switch is in the switch-on state, it is to control the switch to switch off; and if the DC busbar voltage is 0V and the switch is in the switch-off state, it is to maintain the switch-off state of the switch. When the switch-off state of the switch is maintained, it is possible to perform current limitation to the charging process during charging, thus achieving the protection function. With the charging time increasing, the DC busbar voltage increases continuously, and when the DC busbar voltage is increased to the first preset voltage, it is to control the switch to switch on, thus reducing loss on the current limiting resistor.

Herein, the first preset voltage is less than the ending voltage. That is, the switch is switched on when the DC busbar voltage during charging is increased to a relatively high value, rather than at the charging ending time point. The reason is: the longer is the charging time, the slower is the charging rate, and the charging current is decreasing. Therefore, after the DC busbar voltage during charging becomes a relatively high value, it is not necessary to consider the problem of current limitation protection. In order to reduce the loss on the current limiting resistor, the current limiting resistor is shorted.

In some embodiments, the method may further comprise: controlling the switch to switch off if the DC busbar voltage is decreased to below a second preset voltage during discharging of the DC busbar filtering electrolytic capacitor. That is, after the switch is switched on, it is generally maintained in the switch-on state. However, once the DC busbar voltage is decreased to a very low value, it is to control the switch to switch off. After the DC busbar voltage is decreased to a very low value, the charging current during recharging will be relatively high. In order to protect the circuit, the switch is switched off.

As the time constant is a product of the resistance of the current limiting resistor and the capacitance of the DC busbar filtering electrolytic capacitor, and the resistance of the current limiting resistor is constant, the time constant reflects the capacitance of the DC busbar filtering electrolytic capacitor. Therefore, when the capacitance, as reflected by the time constant, is decreased to a certain degree, it is determined that it is necessary to perform maintenance for the DC busbar filtering electrolytic capacitor. It is to set the current time point as the maintenance time point and then inform the user of the maintenance time point, and thus the user is informed that it is necessary to perform maintenance for the DC busbar filtering electrolytic capacitor. The capacitance is used to determine whether it is necessary to perform maintenance and the capacitance may be changed due to influence by surrounding factors, such as temperature, current ripple, voltage ripple, and so on. Therefore, compared with those methods of determining whether it is necessary to perform maintenance depending on the use time period of the electrolytic capacitor, the methods consider practical working circumstances, with more accurate determination for the lifetime of the capacitor. That is, the determination for the maintenance time point is more accurate, thus reducing downtime of the driving motor.

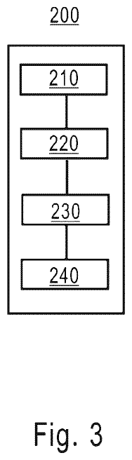

Some embodiments include a device for determining maintenance of a DC busbar filtering electrolytic capacitor. Referring to FIG. 3, the device 200 comprises:
a data recording module 210, for recording a DC busbar voltage of the DC busbar filtering electrolytic capacitor in a driving circuit of a driving motor during charging of the DC busbar filtering electrolytic capacitor wherein the DC busbar voltage is a difference between voltages at two ends of the DC busbar filtering electrolytic capacitor;
a first determination module 220, for determining a charging starting time point and a charging ending time point according to the recorded DC busbar voltages, and selecting a time point from time points between the charging starting time point and the charging ending time point;
a parameter calculation module 230, for calculating a time constant according to a starting voltage corresponding to the charging starting time point, an ending voltage corresponding to the charging ending time point, the selected time point and the DC busbar voltage corresponding to the selected time point; and a second determination module 240, for determining whether it is necessary to perform maintenance for the DC busbar filtering electrolytic capacitor, according to the time constant.

In some embodiments, the parameter calculation module is specifically used for: calculating the time constant by a first formula as below:

$$RC = t / ln [ ( V 1 - V 0 ) / ( V 1 - Vt ) ]$$

wherein RC is the time constant, t is the selected time point, Vt is the DC busbar voltage corresponding to the selected time point, V0 is the starting voltage, and V1 is the ending voltage.

In some embodiments, the first determination module comprises: a first determination unit, used for: if the charging process is the first charging process after power on of the driving circuit, setting the time point at which the DC busbar voltage during charging is 0V as the charging starting time point, and setting the time point at which the DC busbar voltage during charging has a variation amplitude less than a preset amplitude as the charging ending time point.

In some embodiments, the first determination module comprises: a second determination unit, used for: If the charging process is not the first charging process after power on of the driving circuit, setting the time point at which the DC busbar voltage during charging starts increasing as the charging starting time point, and setting the time point at which the DC busbar voltage during charging starts decreasing as the charging ending time point.

In some embodiments, the second determination module is specifically used for: determining that it is necessary to perform maintenance for the DC busbar filtering electrolytic capacitor if the time constant is less than a preset threshold.

In some embodiments, the driving circuit comprises a current limiting resistor and a switch which are connected in parallel; and the device further comprises: a switch controlling module, used for: if the charging process is the first charging process after power on of the driving circuit, controlling the switch to switch off when the DC busbar voltage during charging is 0V, and controlling the switch to switch on when the DC busbar voltage is increased to a first preset voltage less than the ending voltage.

In some embodiments, the switch controlling module is further used for: controlling the switch to switch off if the DC busbar voltage is decreased to below a second preset voltage during discharging of the DC busbar filtering electrolytic capacitor.

The related explanation, specific implementation manner(s), beneficial effect(s), example(s), and the like of the device(s) may refer to the respective portions in the method(s) as provided in the first aspect, and will not be described repeatedly herein.

Some examples include a computer-readable storage medium. It is stored thereon with a computer program, and when the computer program is executed in a computer, one or more of the methods described herein is implemented by the computer. The related explanation, specific implementation manner(s), beneficial effect(s), example(s), and the like of the computer-readable storage medium may refer to the respective portions in the method(s) as provided in the first aspect, and will not be described repeatedly herein.

s another example, some embodiments include a calculation apparatus. It comprises a memory and a processor wherein the memory is stored therein with executable codes, and when the executable codes are executed by the processor, one or more of the methods described herein is implemented. The related explanation, specific implementation manner(s), beneficial effect(s), example(s), and the like of the calculation apparatus as provided in the embodiments of the present invention may refer to the respective portions in the method(s) as provided in the first aspect and will not be described repeatedly herein.

The same or similar portions between different embodiments can be referred to each other. Each embodiment emphasizes in explaining the difference(s) with respect to other embodiment(s). In particular, as the apparatus/device embodiments are substantially similar to the method embodiments, the description thereof is relatively simple, and the description of the method embodiments may be referred to for the related portions.

With the above-described specific embodiments, the purposes, technical solutions and beneficial effects of the present disclosure are further explained in detail. The above description is only for specific embodiments of the present disclosure, not for defining the protection scope thereof. Any variation, equivalent substitution or improvement made based on the technical solutions will fall within the protection scope.

What is claimed is:

1. A method for determining maintenance of a DC busbar filtering electrolytic capacitor, the method comprising:
recording a DC busbar voltage of the DC busbar filtering electrolytic capacitor in a driving circuit of a driving motor during charging of the DC busbar filtering electrolytic capacitor/wherein the DC busbar voltage is defined as a difference between voltages at two ends of the DC busbar filtering electrolytic capacitor;
determining a charging starting time point and a charging ending time point according to the recorded DC busbar voltages, and selecting a time point from time points between the charging starting time point and the charging ending time point;
calculating a time constant according to a starting voltage corresponding to the charging starting time point, an ending voltage corresponding to the charging ending time point, the selected time point and the DC busbar voltage corresponding to the selected time point; and
determining whether it is necessary to perform maintenance for the DC busbar filtering electrolytic capacitor based on the time constant.

2. The method according to claim 1, wherein calculating a time constant comprises calculating the time constant by a first formula:
$$RC = t / ln [ ( V 1 - V 0 ) / ( V 1 - Vt ) ]$$
wherein RC is the time constant, t is the selected time point, Vt is the DC busbar voltage corresponding to the selected time point, V0 is the starting voltage, and V1 is the ending voltage.

3. The method according to claim 1, wherein determining a charging starting time point and a charging ending time point according to the recorded DC busbar voltages comprises,
if the charging process is the first charging process after power on of the driving circuit, setting the time point at which the DC busbar voltage during charging is 0V as the charging starting time point, and setting the time point at which the DC busbar voltage during charging has a variation amplitude less than a preset amplitude as the charging ending time point.

4. The method according to claim 1, wherein determining a charging starting time point and a charging ending time point according to the recorded DC busbar voltages comprises,
if the charging process is not the first charging process after power on of the driving circuit, setting the time point at which the DC busbar voltage during charging starts increasing as the charging starting time point, and setting the time point at which the DC busbar voltage during charging starts decreasing as the charging ending time point.

5. The method according to claim 1, wherein determining whether it is necessary to perform maintenance for the DC busbar filtering electrolytic capacitor according to the time constant comprises
determining that it is necessary to perform maintenance for the DC busbar filtering electrolytic capacitor if the time constant is less than a preset threshold.

6. The method according to claim 1, wherein the driving circuit comprises a current limiting resistor and a switch which are connected in parallel; and
the method further comprises,
if the charging process is the first charging process after power on of the driving circuit, controlling the switch to switch off when the DC busbar voltage during charging is 0V, and controlling the switch to switch on when the DC busbar voltage is increased to a first preset voltage less than the ending voltage.

7. The method according to claim 6, the method further comprising
controlling the switch to switch off if the DC busbar voltage is decreased to below a second preset voltage during discharging of the DC busbar filtering electrolytic capacitor.

8. A device for determining maintenance of a DC busbar filtering electrolytic capacitor, the device comprising:
a data recording module to record a DC busbar voltage of the DC busbar filtering electrolytic capacitor in a driving circuit of a driving motor during charging of the DC busbar filtering electrolytic capacitor wherein the DC busbar voltage is a difference between voltages at two ends of the DC busbar filtering electrolytic capacitor;
a first determination module to determine a charging starting time point and a charging ending time point according to the recorded DC busbar voltages, and selecting a time point from time points between the charging starting time point and the charging ending time point;
a parameter calculation module to calculate a time constant according to a starting voltage corresponding to the charging starting time point, an ending voltage corresponding to the charging ending time point, the selected time point and the DC busbar voltage corresponding to the selected time point; and
a second determination module to determine whether it is necessary to perform maintenance for the DC busbar filtering electrolytic capacitor, according to the time constant.

9-10. (canceled)
